(19) United States
(12) Patent Application Publication
(10) Pub. No.: US 2026/0328858 A1
(43) Pub. Date: Oct. 22, 2026

(54) SYSTEM AND METHOD FOR BATTERY HEALTH MONITORING AND FAULT DETECTION

(71) Applicant: VERTIV CORPORATION, Westerville, OH (US)

(72) Inventors: Mohammad Sadegh AINEHVAND, Ciudad de Mexico (MX); Ashwini GAT, Pune (IN); Lucas Gregory JOHNSON, Delaware, OH (US)

(73) Assignee: VERTIV CORPORATION, Westerville, OH (US)

(21) Appl. No.: 19/529,257

(22) Filed: Feb. 4, 2026

(30) Foreign Application Priority Data
Feb. 4, 2025 (IN) 202521009089

(51) Int. Cl. G01R 31/392; G01R 31/367; G01R 31/371; G01R 31/3842; G06N 20/00; H01M 10/42; H02J 7/60; H02J 7/84; H02J 7/90

(52) U.S. Cl. CPC G01R 31/392; G01R 31/367; G01R 31/371; G01R 31/3842; G06N 20/00; H01M 10/4285; H02J 7/60; H02J 7/84; H02J 7/933

(57) ABSTRACT

A battery health monitoring and fault detection system is disclosed. The system comprising a data collection module to collect real-time data during a controlled charging phase of a battery; a machine learning analysis module to analyze the collected data using machine learning program to identify patterns, anomalies, and deviations in the charging behavior of the battery; a prediction module operatively connected to the machine learning analysis module, to estimate a battery life and detect early stage potential battery fault based on the analyzed data; a control module configured to regulate the controlled charging phase of the battery based on the outputs of the prediction module; and a communication interface configured to enable data transmission to a remote server or cloud-based platform for further analysis and integration with external battery management systems.

### CROSS-REFERENCE TO RELATED APPLICATION

This patent application claims priority to Indian Patent Application No. IN 202521009089, filed on Feb. 4, 2025, entitled “A system and method for battery health monitoring and fault detection,” and assigned to the assignee hereof. The entire disclosure of the above application is incorporated herein by reference.

### TECHNICAL FIELD

The present invention generally relates to the field of electrodiagnostic. More specifically, the present invention relates to monitoring of conditions associated with assessment of battery health, fault detection, and prediction of failure or degradation in battery packs.

### BACKGROUND

Battery health monitoring and fault detection are critical components in modern power management systems, playing a vital role in ensuring the reliability and longevity of batteries used across various applications. With the growing reliance on battery-powered devices, electric vehicles, renewable energy storage systems, and industrial equipment, accurately predicting battery life and identifying faulty batteries has become more important than ever.

Traditional battery health monitoring systems often focus on discharging characteristics to evaluate the battery's condition. One of the primary challenges in battery monitoring lies in the diverse conditions under which batteries operate, including varying ambient temperatures, differences in battery quality, and the wide range of load types they power.

These factors lead to unpredictable degradation patterns, making it difficult to determine the remaining lifespan of a battery accurately. Challenges associated with battery health may relate to predicting battery health, remaining life span (also referred to as State of Health (SOH)), are compounded by operating conditions and external variables. Further, some batteries are highly sensitive to temperature fluctuations. Extreme cold or heat may impact charging or discharging of batteries leading to alteration of internal chemistry within a battery.

Further, the batteries may not be created equal. Variations may be observed even with same model or brands due to factors like impurities, variations in battery's internal construction, inconsistencies in charging cycles during manufacturing. A battery is a collection of two or more cells connected together, to provide higher voltage or capacity, wherein a cell is the basic, single unit that converts chemical energy to electrical energy. Furthermore, variations in aging of cells may be observed. A single weak cell may degrade a performance of an entire pack, but this may be difficult to detect early without detailed monitoring of each cell.

Further, load demands placed on battery may vary greatly depending on application using the battery. The load demands may include a constant load, a dynamic load, or a pulse load. Variation in type of load may lead to variation in type of battery degradation patterns. Prediction of battery degradation based on historical usage patterns and load profiles may play a key role in accurately forecasting battery faults. Furthermore, multiple problems may arise due to battery's complex degradation mechanisms and complex charge or discharge patterns.

### SUMMARY OF THE INVENTION

This summary is provided to introduce aspects related to system and method for battery health monitoring and fault detection. The disclosed system incorporates a data collection module configured to capture or collect real time-data, a machine learning analysis module, a prediction module, a control module and a communication interface.

In an aspect, a battery health monitoring and fault detection system, comprises: a data collection module configured to collect real-time data during a controlled charging phase of a battery; a machine learning analysis module configured to process or analyze the collected data using machine learning program to identify patterns, anomalies, and deviations in a charging behavior of a battery; a prediction module operatively connected to the machine learning analysis module, configured to estimate the battery life expectancy and detect potential battery faults based on the analyzed data; a control module configured to regulate the controlled charging phase based on the outputs of the prediction module, thereby optimizing battery performance and ensuring early fault detection; and a communication interface configured to enable data transmission to a remote server or cloud-based platform for further analysis and integration with external battery management systems.

In another aspect, data collection module further comprises sensors configured to measure environmental factors that affect battery performance, including but not limited to an ambient temperature, a humidity indicator, and a pressure indicator.

In another aspect, data includes parameters such as a voltage of the battery before the controlled charging phase begins, a voltage immediately after the controlled charging phase begins, a voltage at specific intervals during the controlled charging phase, voltage immediately before the controlled charging phase ends, a voltage at immediately after the end of the controlled charging phase, a voltage at intervals following the end of the controlled charging phase, an ambient temperature, and a charging current.

In another aspect, the system is universally applicable to any battery type, regardless of its chemical composition or manufacturer.

In another aspect, machine learning analysis module utilizes a combination of supervised learning techniques, such as regression and classification program, to improve the accuracy of fault detection and battery life predictions.

In one aspect, prediction module is further configured to generate a visual dashboard representation of battery health status and projected lifespan for user interaction and monitoring.

In one aspect, data communication interface supports connectivity with external battery management systems using standard communication protocols, such as Bluetooth, Wi-Fi, or cellular networks, to facilitate remote monitoring and diagnostics.

In one aspect, machine learning analysis module further comprises a feature extraction unit configured to derive key parameters such as voltage decay rate, charge acceptance, and temperature fluctuations, which are indicative of battery health and performance.

In one aspect, control module includes an adaptive learning capability that dynamically updates a set of charging parameters based on the ongoing performance and battery health status, thereby enhancing charging efficiency and lifespan.

In one aspect, machine learning analysis module integrates with a data visualization interface that generates detailed charts and graphs depicting real-time battery performance trends, charge cycles, and fault indicators for end-users.

In one aspect, data collection module designed to operate under diverse environmental conditions ensuring consistent performance of the battery monitoring system, the diverse environmental conditions including an extreme temperature, a high humidity, and a range of pressure levels.

In one aspect, machine learning analysis module employs classification program to categorize battery faults into distinct types to enable targeted corrective actions, the distinct types of battery faults comprising an overcharging voltage, a thermal runaway, and a capacity degradation indicator.

In one aspect, machine learning analysis module utilizes a neural network architecture specifically optimized for anomaly detection, enabling the identification of subtle deviations in the charging behavior of the battery that may indicate an early-stage battery fault.

In one aspect, machine learning analysis module includes an adaptive learning algorithm that continuously refines its predictive models by incorporating new charging cycle data, to improve the precision of battery life expectancy estimates.

In one aspect, the system further comprises a user notification interface configured to send alerts and recommendations to users or maintenance personnel via mobile applications or email when potential battery issues are detected, ensuring timely intervention and reducing downtime.

In an aspect, a method for battery health monitoring and fault detection during a controlled charging phase of a battery, the method comprising the steps of: collecting real-time data during a controlled charging phase of a battery, including voltage measurements before and after charging begins, at intervals during charging, and at intervals following the end of charging, as well as ambient temperature and charging current; analyzing the collected data using machine learning program to identify patterns, anomalies, and deviations indicative of battery health status; predicting the battery's remaining lifespan and potential faults based on observed changes in voltage, current, and internal resistance characteristics; generating alerts for early detection of potential battery failures to enable predictive maintenance; and regulating the controlled charging phase to optimize battery performance and extend its lifespan based on the analysis of the charging phase data.

In another aspect, the method further includes a step of integrating the analysis results with a cloud-based platform for centralized monitoring and predictive analytics of multiple battery systems across diverse locations.

In another aspect, the method further includes a step of generating predictive analytics reports that highlight potential failure risks and recommend proactive measures for maintaining optimal battery health across different applications.

In one aspect, the said control module dynamically adjusts the set of charging parameters in response to the detected battery condition to prevent overcharging, overheating, or any other adverse effects that could reduce battery life.

In one aspect, the data collected during the charging phase is subjected to preprocessing techniques, including noise reduction and data normalization, to improve the robustness and reliability of the machine learning model's output.

In one aspect, the method further comprises the step of periodically updating the machine learning model with new data to continuously refine the accuracy of battery life predictions and fault detection.

In one aspect, the battery health monitoring system is configured to operate on both local devices and remote servers, ensuring flexibility in deployment depending on the application environment.

In one aspect, the method further comprises the step of validating the predictions of the battery life and fault detection model using historical data sets to improve accuracy and reduce false positives.

In one aspect, adapting to changes in battery chemistry or charging conditions in real-time, the method performs self-calibration during the charging phase to fine-tune the accuracy of the battery life predictions.

In one aspect, the method further comprises a step of performing real-time adjustment of the set of charging parameters based on the ambient temperature data, optimizing the controlled charging phase to prevent overheating and extend battery lifespan.

In one aspect, the method further comprises the step of generating a maintenance schedule based on the predicted battery health data, enabling proactive replacement or repair of batteries before failure occurs.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIG. 1 illustrates a block diagram for battery health monitoring and fault detection in accordance with an embodiment of the present disclosure.

FIG. 2 illustrates a flow diagram for battery health monitoring and fault detection, in accordance with an embodiment of the present invention.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label irrespective of the suffix.

### LIST OF REFERENCE NUMERALS

100—System for battery health monitoring and fault detection
102—Data collection module
104—Machine Learning analysis module
106—Prediction module
108—Control module
110—Communication Interface
200—Method for monitoring battery health and detecting faults
202—Step for real-time data collection
204—Step for preprocessing of collected data
206—Step for analysis of pre-processed data
208—Step for prediction of battery health
210—Step for validation of predictions.
212—Step for calibration of reference base lines
214—Step for dynamic control of charging parameters
216—Step for generation of alerts for early fault detection
218—Step for generation of predictive maintenance schedule
220—Step for cloud integration of results.
222—Step for data storage and aggregation within a secure cloud based platform
224—Step for updating of machine learning model.

### DETAILED DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

Battery health monitoring and fault detection are critical components in modern power management systems, playing a vital role in ensuring the reliability and longevity of batteries used across various applications. With the growing reliance on battery-powered devices, electric vehicles, renewable energy storage systems, and industrial equipment, accurately predicting battery life and identifying faulty batteries has become more important than ever.

Traditional battery health monitoring systems often focus on discharging characteristics to evaluate the battery's condition. One of the primary challenges in battery monitoring lies in the diverse conditions under which batteries operate, including varying ambient temperatures, differences in battery quality, and the wide range of load types they power. These factors lead to unpredictable degradation patterns, making it difficult to determine the remaining lifespan of a battery accurately.

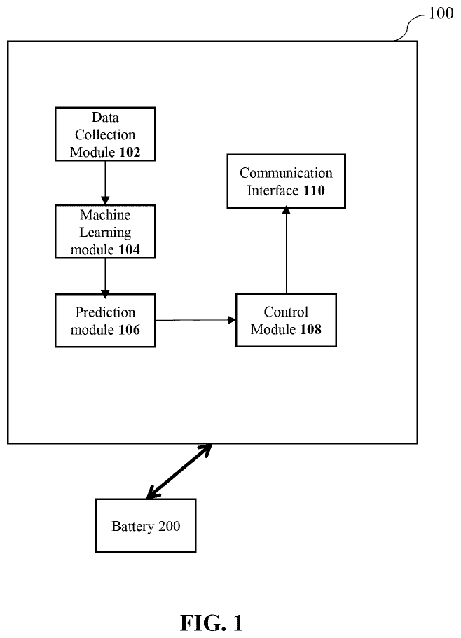

FIG. 1 illustrates a block diagram of a system 100 for battery health monitoring and fault detection in accordance with an embodiment of the present disclosure. The system 100 consists of a data collection module 102, a machine learning analysis module 104, a prediction module 106, a control module 108, and a communication interface 110. The system 100 may be aimed at monitoring battery health, detection of fault, collection of data in real time, implementation of machine learning and providing a predictive modelling to manage health of a battery over a lifecycle of the battery. In an embodiment, the system may be configured to monitor battery health and detect the fault irrespective of underlying cell chemistry, making it universally applicable to lithium-ion, lead-acid, nickel-metal hydride, solid state or any other battery type.

The system 100 may have a battery 200 operably connected to the system 100. FIG. 1 illustrates an architecture configured to employ chemistry-agnostic sensing and collection of a set of parameters associated with the connected battery 200, as the set of parameters comprising voltage, response patterns, temperature gradients, internal resistance trends, current flow characteristics, State Of Health (SOH) indicators. The set of parameters may be processed through adaptive algorithms automatically calibrating specific electrochemical behavior of the connected battery. Such architecture may lead to uniform fault detection, early anomaly identification, and predictive maintenance across diverse batteries without requiring hardware or software modification.

In one embodiment, the data collection module 102 may be configured to capture or collect real-time data during the charging cycle of battery 200. The data collection module 102 may collect critical parameters for a battery such as a voltage, a current, and an ambient temperature at specific intervals throughout the charging phase.

The voltage parameter may be an important indicator associated with health of the battery and changes in the voltage may reflect issues like degradation, overcharging or internal resistance build up. Further, an amount of current flowing into or out of the battery during charging or discharging phase may give an insight into the battery's energy flow and efficiency.

By focusing on the controlled charging environment, the data collection module 102 may ensure that consistent and reliable, data is gathered, which is essential for accurate analysis.

The data collection module 102 may be equipped with high-precision sensors configured to measure these parameters to deliver detailed insights into the charging behavior of the battery 200, making it suitable for batteries of varying chemistries and designs. The sensors may ensure accurate collection of data and monitor even small variations in voltage or current. Further, the data collection module 102 may be configured to capture or collect data at regular intervals, the data captured at regular intervals depict behavior of the battery and minimize errors from transient events, the transient events may relate to momentary spikes or dips in voltage.

In one embodiment, the data collection module 102 may be configured to accommodate different battery chemistries and designs.

The system 100 may be further configured to include a machine learning analysis module 104 to use a sophisticated program designed to process the data collected by the data collection module 102. The machine learning analysis module 104 may be configured to identify patterns, anomalies, and deviations in the charging behavior of the battery 200 after collection of data by the data collection module 102.

By employing machine learning techniques, such as regression analysis, classification program, or neural networks, the module learns from the historical charging data to detect subtle irregularities that may indicate potential issues in battery performance. The machine learning module 104 may recognize patterns in the charging and discharging behavior of the battery 200 over time.

By doing so, the machine learning module 104 may identify normal vs. anomalous behavior, leading to identification of any potential degradation or failure modes before such degradation or failure becomes critical. The machine learning model 104 may be configured to learn over time, a vast number of data points related to normal and abnormal behavior of the battery.

In one implementation, the machine learning module 104 may be configured to analyze degradation of the battery health without analyzing long term trends. Further, the machine learning module 104 may be trained on historical charging cycles, the historical charging cycles help to improve abilities to detect issues over time. Further, the machine learning module 104 may be configured to use techniques like regression analysis, the regression analysis aimed to predict continuous variables such as remaining capacity or voltage decay over time.

In one embodiment, the machine learning module 104 may be configured to perform a categorization of data into groups, the categorization may be based on behavior of the battery. Further, the machine learning module 104 may be configured to use neural networks, wherein the neural networks may employ one or more deep learning models, the deep learning models employed to captured complex, non-linear relationships between different parameters influencing the battery health.

In one embodiment, the machine learning module 104 may be configured to perform feature engineering, wherein the feature engineering includes selecting, transforming, or creating the best set of input parameters (or “features”) that the machine learning model will use to make its predictions. The features associated with the operation of feature engineering may include rate of voltage change during charge or discharge cycles, the peak temperature during charging, total charge cycles and depth of charge, and resistance growth over time.

In one embodiment, the machine learning module 104 may be configured to be trained using labeled datasets, the labelled datasets may include conditions already flagged before, the conditions may include “battery failure”, “optimal health” or “early degradation”. In one embodiment, the supervised learning techniques such as regression or classification models may be used to train the machine learning model 104.

The regression models may predict continuous outputs, such as the remaining useful life (RUL) or capacity loss rate based on historical data. Further, the supervised learning may include classification models, wherein the classification models are aimed at categorization of the battery health into discrete states, the states may help to identify a point where specific intervention may be required.

In one embodiment, the unsupervised learning may be used when the labelled data is not available for detecting issues that were not a part of training data. Further, the machine learning module 104 may use various types of machine learning algorithms, the machine learning algorithms may include decision and random tree forests to understand reasoning behind predictions associated with the battery health, support vector machines when dealing with high dimensional data, neural networks, neural networks models to process sequential data like time series data from battery voltage and current measurements, and k means clustering to detect unknown patterns or anomalies indicating potential issues associated with degradation of the battery health.

In an embodiment, the machine learning module 104 may include a feature extraction unit configured to derive key parameters such as voltage decay rate, charge acceptance rate, temperature fluctuations, internal resistance variation, cycle wise capacity retention etc. The features extracted may construct data sets for machine learning model enabling an accurate prediction of the battery health, early detection of fault, and adaptive recalibration across different operating condition and battery chemistries.

In one embodiment, the machine learning analysis module 104 may integrate with a data visual interface configured to generate a representation for end users, depicting a set of battery attributes, the set of battery attributes comprising a real time battery performance trends, a charge cycle and a fault indicator. The data visual interface may translate output from the machine learning analysis module 104 into an intuitive visual format such as detailed charts and tables, enabling a real-time interpretation of complex data.

In one embodiment, by machine learning analysis performed by the machine learning module 104, the system 100 may make predictive maintenance recommendations. In another embodiment, the prediction module 106 may be operatively connected to the machine learning analysis module 104 and plays a crucial role in estimating the battery life expectancy and detecting possible faults. In an embodiment, the machine learning analysis module 104 may use an adaptive learning algorithm aimed to refine the predictive model used in the predictive module 106 in a continuous manner. Such adaptive learning algorithm may improve the precision of battery life estimate.

The prediction module 106 may utilize the patterns and anomalies identified by the machine learning analysis module 104 to forecast the remaining lifespan of the battery 200, enabling proactive measures to be taken before a failure occurs. The prediction module 106 may integrate a variety of data points, such as voltage decay rates and temperature fluctuations, to offer precise life expectancy estimates, thereby facilitating predictive maintenance strategies for optimal battery utilization.

By accurately predicting when a battery is nearing the end of its useful life or when it's likely to fail, the prediction module 106 may allow for proactive maintenance, helping to prevent unexpected downtime or catastrophic failures. In addition to forecasting remaining lifespan of the battery, the prediction module 106 may guide battery users or operators to optimize charging cycles, such as recommending when to slow down charging rates to prevent stress or overheating.

In an embodiment, the prediction module 106 may be configured to generate visual dashboard representation of battery health status and a projected battery lifespan for user interaction and monitoring, wherein the prediction module 106 may monitor and analyze real-time and historical performance parameters such as charge or discharge cycles, capacity fade, temperature variations, internal resistance trends and future degradation patterns. The parameters post analysis may be displayed through an intuitive dashboard interface that enables users to monitor current metrics, receive early warning of potential faults, and view predictive lifespan estimates in an early interpretable visual format.

In yet another embodiment, the control module 108 may be designed to regulate the controlled charging phase based on the insights provided by the prediction module 106. The control module 108 may adjust the set of charging parameters to optimize battery performance and prevent conditions that could lead to premature degradation, such as overcharging or overheating.

The Control module 108 may ensure that battery is charged within safe limits, preventing overcharging, which can accelerate degradation and even cause thermal runaway. By implementing real-time control over the charging cycle, the control module 108 ensures that the battery remains in optimal health, reducing the risk of unexpected failures and extending its overall lifespan. In one embodiment, the control module 108 is linked to Battery Management System (BMS) (not shown) for reliable operation of the system 100.

In one embodiment, the communication interface 110 facilitates the seamless transmission of data to remote servers or cloud-based platforms for further analysis. The communication interface 110 may play a critical role in ensuring that the insights gained from the system are shared with maintenance teams, operators, or end-users. In an embodiment, a notification interface may be linked with a communication interface configured to transmit health report alerts, predictive insights etc. to an external device or cloud platform. The communication interface 110 may use a wired or wireless communication protocols such as CAN, UART, Bluetooth, Wi-Fi, Cellular networks enabling a seamless data exchange between monitoring system and a remote supervisory unit. An integration of communication interface 110 with the notification interface may ensure a real-time delivery of battery status information, remote diagnostics and over the air updates.

Further, the communication interface may enable a real-time transmission of health data, predictions, and any warnings about potential faults to remote systems, cloud platforms, or a centralized monitoring system.

The aforementioned feature may allow operators or users to receive up-to-date information on battery health, even if they are at a remote location away from the physical location of the battery.

Further, the communication interface 110 may support integration with external battery management systems, enabling centralized monitoring and management of battery health across multiple devices. The communication interface 110 ensures the analyzed data and predictions can be accessed and utilized in real-time by maintenance teams or end-users for decision-making.

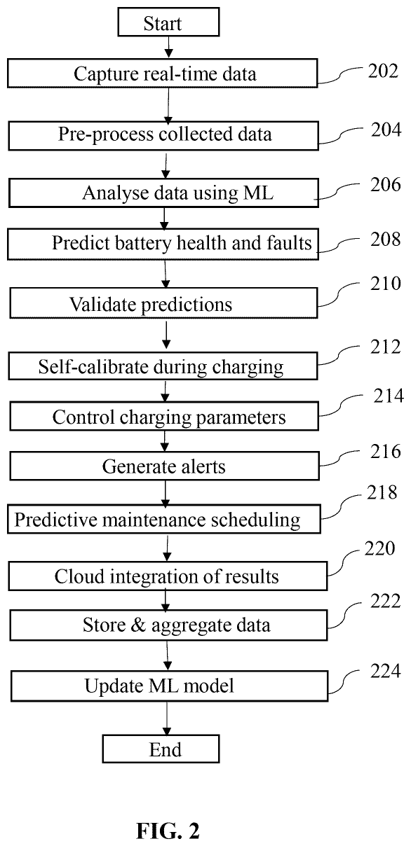

FIG. 2 illustrates a method 200 for monitoring battery health and detecting faults during the charging phase. The method 200 begins at step 202, wherein real-time data related to the controlled charging phase is captured or collected by the data collection module (similar to data collection module referred in FIG. 1).

The real-time data may include a pre-charging voltage, voltage at predetermined intervals during charging cycle, a post-charging voltage, a charging current, an ambient temperature, and time-stamped charging events.

In one embodiment, the real-time data may be obtained from sensors integrated directly into a Battery Management System (BMS). In another embodiment, the real-time data may be collected by a charger using embedded measurement circuitry. In yet another embodiment, wireless sensors communicate environmental and current-flow data to the system via Bluetooth Low Energy (BLE), Wi-Fi, Zigbee etc.

At step 204, the collected real-time data may undergo preprocessing to improve the integrity of subsequent analysis. Preprocessing may include filtering noise using one or more digital filters (e.g., low-pass, moving average, or Kalman filters), normalizing data to eliminate scale variations, and removing erratic outlier samples caused by measurement disturbances.

In an embodiment, preprocessing may further include temperature compensation or time-alignment of samples from multiple sensors to ensure synchronized analysis of voltage and current curves.

At step 206, the preprocessed data is analyzed using a machine learning (ML) program in the machine learning analysis module (similar to the machine learning analysis module of FIG. 1). The machine learning program may identify patterns within the charging behavior of the battery, detect anomalies such as unexpected voltage drops, unstable current draw, or irregular charging plateaus, and identify deviations indicating early degradation.

In one embodiment, the machine learning module may utilize neural networks trained on historical battery operation datasets. In another embodiment, lightweight models such as decision trees or SVM classifiers are deployed directly on the battery device for low-latency inference. In a cloud-based embodiment, data may be uploaded to a remote analytics server that performs large-scale pattern recognition across thousands of charge cycles.

Based on the aforementioned analysis, a prediction module (similar to prediction module of FIG. 1), at step 208, may predict health of the battery, including the remaining useful life (RUL), expected failure timelines, or detection of early-stage internal faults. Faults may include cell imbalance, increasing internal resistance, over-temperature tendencies, or deteriorating charge-retention capability.

In an embodiment, the prediction module may perform cell-level predictions rather than pack-level predictions. In another embodiment, the prediction models may utilize fleet-level training data from numerous batteries deployed in similar applications.

Further, the prediction module may validate the machine learning based predictions using historical datasets. Validation may include comparing predicted voltage profiles with earlier charge cycles, matching anomalies with previously known failure signatures, or computing a confidence score associated with each predicted fault.

In one embodiment, the historical data may be stored locally on the device for offline validation. In another embodiment, the validation may be performed against a cloud-hosted database containing patterns from a wide variety of battery chemistries.

At step 210, the system may perform validation of predictions for self-calibration during the charging phase. This calibration may compensate for sensor drift, battery aging, or environmental variation.

In one embodiment, the method 200, at step 212, may include recalibrating voltage reference baselines, dynamically adjusting internal ML parameters, or updating resistance estimation models to reflect changing battery chemistry over time. In another embodiment, self-calibration may include automatically adjusting thresholds for anomaly detection.

A control module (similar to the control module of FIG. 1) at Step 214 may involve dynamic controlling of a set of charging parameters based on the detected condition associated with the battery health. The control module may increase or decrease the charging current, adjust a charging voltage, slow down the charging rate during high-temperature conditions, or initiate a protective cutoff procedure when a dangerous anomaly is detected.

In one embodiment, the control module at step 214 may modify a constant-current phase (CC) or a constant-voltage (CV) phase to optimize battery longevity. In another embodiment, the charger using embedded measurement circuitry may communicate with the BMS to maintain ideal thermal conditions.

At step 216, the control module may generate alerts for early fault detection. The alerts may include warnings for elevated temperature, rapidly increasing internal resistance, abnormal voltage fluctuation, or early indicators of battery degradation.

In one embodiment, at step 216, the method 200 may include sending notifications to a user's mobile device, warnings displayed on a vehicle dashboard, or automatic alerts via communication interface (similar to the communication interface of FIG. 1).

Step 218 may include generation of a predictive maintenance schedule based on the predicted battery health metrics. The battery health metrics may include recommended battery replacement intervals, servicing timelines, cell rebalancing events, or usage optimization guidelines. In one embodiment, the system may predict the specific date or number of cycles remaining before a likely failure. In another embodiment, the system may provide actionable guidance to extend battery life, such as limiting charging at high temperatures.

At step 220, the analysis results and operational data may be integrated with a cloud-based platform. Integration of cloud-based platform may enable centralized monitoring of multiple batteries deployed across remote or distributed locations. In one embodiment, the cloud-based platform may aggregate data from electric vehicle fleets. In another embodiment, it visualizes performance trends across renewable energy battery banks.

At step 222, the data may be stored and aggregated within a secure cloud database. The data stored may enable long-term tracking of battery condition and comparison across similar battery systems.

Finally, at step 224, the machine learning model is periodically updated using newly collected data. Updates may be performed locally, remotely, or using a federated learning approach where multiple distributed devices contribute to continuous model improvement without sharing raw data.

In one embodiment, updates may occur automatically after a targeted number of charge cycles. In another embodiment, updates may be scheduled during low-usage periods to minimize operational impact.

The foregoing description of the embodiments has been provided for purposes of illustration and is not intended to limit the scope of the present disclosure. Individual components of a particular embodiment are generally not limited to that particular embodiment, but, are interchangeable. Such variations are not to be regarded as a departure from the present disclosure, and all such modifications are considered to be within the scope of the present disclosure.

The present disclosure described herein above has several technical advantages including, but not limited to, the battery health monitoring and fault detection, which:
i) provides real-time analysis of battery health by focusing on the charging phase rather than discharging, enhancing the accuracy of life expectancy predictions;
ii) provides universal applicability by eliminating the need for specific knowledge of battery chemistry or manufacturer design;
iii) provides early detection of battery faults through machine learning program, allowing for proactive maintenance and reducing the risk of unexpected failures;
iv) provides scalable deployment options through cloud-based platforms or device-level integration, ensuring adaptability across different environments; and
v) provide more machine learning-friendly data from a controlled charging state instead of an uncontrolled discharging state.

The use of the expression “at least” or “at least one” suggests the use of one or more elements or ingredients or quantities, as the use may be in the embodiment of the disclosure to achieve one or more of the desired objects or results.

The methods, systems, devices, graphs, and/or tables discussed herein are examples. Various embodiments may omit, substitute, or add various procedures or components as appropriate. For instance, in alternative embodiments, the methods may be performed in an order different from that described, and/or various stages may be added, omitted, and/or combined.

Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as limitation on the scope of the disclosure.

We claim:

1. A battery health monitoring system comprising:
a data collection module configured to collect real-time data during a controlled charging phase of a battery connected to the system;
a machine learning analysis module to analyze the collected data using machine learning program to identify patterns, anomalies, and deviations in a charging behavior of the battery;
a prediction module operatively connected to the machine learning analysis module, to estimate a battery life prediction or to detect potential battery faults based on the analyzed data;
a control module configured to regulate the controlled charging phase of the battery based on the outputs of the prediction module; and
a communication interface configured to enable data transmission to a remote server or a cloud-based platform for further analysis and integration with an external battery management system.

2. The system as claimed in claim 1, wherein said data collection module further comprises a sensor configured to measure at least one environmental factor that affect battery performance, the environmental factor is selected from the group comprising an ambient temperature, a humidity indicator, and a pressure indicator.

3. The system as claimed in claim 1, wherein said captured data includes at least one of a voltage before charging phase starts, a voltage immediately after the charging phase starts, a voltage at specific intervals during the charging phase, an ambient temperature, a charging current, a voltage immediately after charging phase ends, voltage at intervals following the end of the charging phase, and a voltage immediately before the charging phase ends.

4. The system as claimed in claim 1, wherein said system is universally applicable to any battery type, regardless of chemical composition or manufacturer of the battery.

5. The system as claimed in claim 1, wherein said machine learning analysis module utilizes a combination of supervised learning techniques to improve the accuracy of fault detection and battery life predictions.

6. The system as claimed in claim 1, wherein said prediction module is further configured to generate an interactive visual dashboard representation for a user to monitor a battery health status and a projected battery lifespan.7.

7. The system as claimed in claim 1, wherein data communication interface (110) supports connectivity with an external battery management system using a standard communication protocol to facilitate remote monitoring and diagnostics, wherein the standard communication protocol uses at least one of a Bluetooth connection, a Wi-Fi network connection, or a cellular network connection.

8. The system as claimed in claim 1, wherein said machine learning analysis module further comprises a feature extraction unit configured to derive key parameters that are indicative of battery health and performance, the key parameters comprising at least one of a voltage decay rate, a charge acceptance rate, and a temperature fluctuation rate.

9. The system as claimed in claim 1, wherein said control module includes an adaptive learning capability to dynamically update a set of charging parameters based on the ongoing performance of the battery and a health status of the battery.

10. The system as claimed in claim 1, wherein said machine learning analysis module integrates with a data visualization interface for end-users that generates a graphical user interface depicting a set of battery attributes, the set of battery attributes comprising a real-time battery performance trend, a charge cycle data, and a battery fault indicator.

11. The system as claimed in claim 1, wherein said data collection module is designed to operate under diverse environmental conditions ensuring consistent performance of the battery monitoring system, the diverse environmental conditions including an extreme temperature, a high humidity, and a range of pressure levels.

12. The system (100) as claimed in claim 1, wherein said machine learning analysis module (104) employs classification program to categorize battery faults into distinct types to enable targeted corrective actions, the distinct types of battery faults including an overcharging, a thermal runaway, and a capacity degradation.

13. The system as claimed in claim 1, wherein said machine learning analysis module utilizes a neural network architecture optimized for anomaly detection, enabling the identification of subtle deviations in charging behavior for indicating an early-stage battery fault.

14. The system as claimed in claim 1, wherein said machine learning analysis module includes an adaptive learning algorithm that continuously refines its predictive models by incorporating new charging cycle data, to improve the precision of battery life predictions.

15. The system as claimed in claim 1, wherein said system further comprises a user notification interface configured to send alerts and recommendations to at least one of a user and a maintenance personnel, via a mobile application or an email upon detecting early stage battery fault, ensuring timely intervention and reducing downtime.

16. A method for monitoring a health of a battery during a controlled charging phase, the method comprising:
collecting real-time data during the controlled charging phase of the battery, the real time data comprising: an ambient temperature, a voltage data and a charging current, wherein the voltage data comprising a voltage before the controlled charging phase begins, a voltage after the controlled charging phase begins,, a voltage at intervals during the controlled charging phase,, and a voltage at intervals following the end of controlled charging phase;
analyzing the collected data using machine learning program to identify at least of one a pattern, an anomaly, and a deviation indicative of battery health status;
estimating a battery life prediction or an early stage battery fault based on observed changes in the voltage data, the charging current, and a set of internal resistance characteristics of the battery;
generating an alert upon detecting an early stage battery fault to enable predictive maintenance; and
regulating the controlled charging phase based on analysis of the collected data to optimize battery performance and extend battery life.

17. The method as claimed in claim 16, further comprising the step of integrating the results of collected data analysis with a cloud-based platform for centralized monitoring and predictive analytics of multiple battery systems across diverse locations.

18. The method as claimed in claim 16, further comprising the step of generating predictive analytics reports that indicates potential failure risks and recommending proactive measures for maintaining optimal battery health across different applications.

19. The method as claimed in claim 16, further comprising dynamically adjusting asset of charging parameters in response to detecting the early stage battery fault to prevent one or more of an overcharging, an overheating, a thermal runaway, a capacity degradation, or other faults adversely impacting the life of the battery.

20. The method as claimed in claim 16, further comprising subjecting the collected data to preprocessing techniques, including noise reduction and data normalization, to improve the robustness and reliability of the machine learning model's output.

21. The method as claimed in claim 16, further comprising the step of aggregating and storing the collected data in a secure cloud database, enabling cross-referencing of battery health patterns with data from similar battery systems for enhanced predictive maintenance.

22. The method as claimed in claim 16, further comprising the step of periodically updating the machine learning model with new data to continuously refine the accuracy of battery life predictions and fault detection.

23. The method as claimed in claim 16, further comprising implementing said battery health monitoring method on both local devices and remote servers, ensuring flexibility in deployment depending on the application environment.

24. The method as claimed in claim 16, further comprising the step of validating the predictions of the battery life and fault detection model using historical data sets to improve accuracy and reduce false positives.

25. The method as claimed in claim 16, further comprising the step of performing self-calibration during the charging phase to fine-tune the accuracy of the battery life predictions, adapting to changes in battery chemistry or charging conditions in real-time.

26. The method as claimed in claim 16, further comprising the step of performing real-time adjustment of the set of charging parameters based on the ambient temperature data, optimizing the charging process to prevent overheating and extend battery lifespan.

27. The method as claimed in claim 16, further comprising the step of generating a maintenance schedule based on the battery life prediction, for enabling proactive replacement or repair of batteries before failure occurs.
